(19) United States
(12) Patent Application Publication
(10) Pub. No.: US 2014/0167293 A1
(43) Pub. Date: Jun. 19, 2014

(54) INTEGRATED CIRCUIT WITH BUMP CONNECTION SCHEME

(71) Applicant: SK HYNIX INC., Gyeonggi-do (KR)

(72) Inventors: Dong-Uk LEE, Gyeonggi-do (KR); Young-Ju KIM, Gyeonggi-do (KR); Keun-Soo SONG, Gyeonggi-do (KR)

(73) Assignee: SK HYNIX INC., Gyeonggi-do (KR)

(21) Appl. No.: 13/830,804

(22) Filed: Mar. 14, 2013

(30) Foreign Application Priority Data
Dec. 13, 2012 (KR) 10-2012-0145330

(51) Int. Cl. H01L 23/00

(52) U.S. Cl. CPC H01L 24/06
USPC 257/786

(57) ABSTRACT

An integrated circuit includes first and second bump pads spaced from each other with a first space, configured to receive differential signals for a normal operation, and at least one redundant bump pad spaced from the first bump pad with a second space smaller than the first space, configured to receive a signal for a repair to the differential signals.

### CROSS-REFERENCE TO RELATED APPLICATIONS

The present application claims priority of Korean Patent Application No. 10-2012-0145330 filed on Dec. 13, 2012, which is incorporated herein by reference in its entirety.

### BACKGROUND

1. Field

Exemplary embodiments of the present invention relates to semiconductor design technology, and more particularly, to an integrated circuit with a bump connection scheme.

2. Description of the Related Art

In general, integrated circuits, such as double data rate synchronous DRAM (DDR SDRAM), have been developed in various fields (e.g., packaging field) to satisfy users' demands. Recently, a mufti chip package (MCP) has been proposed as a technology of packaging high-capacity integrated circuits. The MCP, in which a plurality of semiconductor chips are included, may increase capacity of an integrated circuit by using semiconductor chips of the same kind or may improve performance by using heterogeneous semiconductor chips. For reference, the MCP may be classified into a single-layered MCP and a multilayered MCP in accordance with the configuration. A plurality of semiconductor chips are arranged in parallel on a plane in the single-layered MCP, while a plurality of semiconductor chips are stacked in the multilayered MCP.

In the related art, the multilayered MCP was implemented by a wire bonding connection scheme. However, the wire bonding connection scheme is vulnerable to various noises and not appropriate for a high-speed operation, so that a bump connection scheme is substituted for the wire bonding at present.

In the bump connection scheme, a plurality of bump pads are arranged at the same positions of respective semiconductor chips and the plurality of bump pads of the adjacent semiconductor chips are connected to each other through bumps. Further, it may also minimize the entire area of an MCP, thus it is considered as a one of promising technologies.

FIG. 1 is a diagram illustrating an arrangement of bump pads in a conventional integrated circuit with a bump connection scheme.

Referring to FIG. 1, the conventional integrated circuit has a plurality of bump pads for inputting/outputting various signals. A first bump pad 110 receiving a main clock signal CK (hereinafter, referred to as a positive main clock signal) a second bump pad 120 receiving a redundant clock signal CL_RED (hereinafter, referred to as a positive redundant clock signal) with the same phase as that of the positive main clock signal CK, a third bump pad 130 receiving a complementary main clock signal CKB (hereinafter, referred to as a negative main clock signal) with an opposite phase to that of the positive main clock signal CK, and a fourth bump pad 140 receiving a complementary redundant dock signal CKB_RED (hereinafter, referred to as a negative redundant clock signal) with the same phase as that of the negative main clock signal CKB. Further, the first and second bump pads 110 and 120 each receiving the positive main clock signal CK and the positive redundant clock signal CK_RED are laterally arranged, and the third and fourth bump pads 130 and 140 each receiving the negative main clock signal CKB and the negative redundant clock signal CKB_RED are arranged longitudinally to the first and second bump pads 110 and 120, respectively.

As described above, the integrated circuit receives the positive main clock signal CK and the positive redundant clock signal CK_RED with the same phase, and similarly receives the negative main clock signal CKB and the negative redundant clock signal CKB_RED with the same phase. The reason that the integrated circuit receives two clock signals with the same phase at a time is because the connection status of the bump pads may become abnormal. In other words, if a defect is generated in the connection status of the bump pads when the integrated circuit is to receive only positive/negative main clock signals CK and CKB, the integrated circuit may not receive positive/negative main clock signals CK and CKB, thus a serious concern may arise in the operation of the circuit. Therefore, the integrated circuit additionally receives positive/negative redundant dock signals CK_RED and CKB_RED with the same phase as those of positive/negative main clock signals CK and CKB to receive and use positive/negative redundant clock signals CK_RED and CKB_RED instead of positive/negative main dock signals CK and CKB.

On the other hand, the sizes of integrated circuits are more and more reduced with the increasing development of processing technologies. The reduction in size of the integrated circuits means that the spaces between internal circuits disposed in the integrated circuits decrease, and this the spaces between bump pads may to decrease, so the possibility of a short between the adjacent bumps may increase.

Therefore, when a short occurs between the adjacent first and second bump pads 110 and 120, the integrated circuits may not receive a clock signal corresponding to the positive main clock signal CK. Further, when a short occurs between the adjacent third and fourth bump pads 130 and 140, the integrated circuits may not receive a clock signal corresponding to the negative main clock signal CKB. As a result, the integrated circuits may not secure desired clock signals even when they receive the positive/negative redundant clock signals CK_RED and CKB_RED in addition to the positive/negative main clock signals CK and CKB. Therefore, the integrated circuits may not perform normal operations.

### SUMMARY

Exemplary embodiments of the present invention are directed to an integrated circuit that may secure a desired signal, although a short occurs between adjacent bump pads.

In accordance with an embodiment of the present invention, an integrated circuit includes first and second bump pads spaced from each other with a first space, configured to receive differential signals for a normal operation, and at least one redundant bump pad spaced from the first bump pad with a second space smaller than the first space, configured to receive a signal for a repair to the differential signal.

In accordance with another embodiment of the present invention, an integrated circuit includes first bump pad configured to receive a main signal, a second bump pad, which is spaced from the first bump pad with a first space, configured to receive a redundant signal having the same phase as the phase of the main signal, a third bump pad configured to receive a complementary main signal having a phase opposite to the phase of the main signal, and a fourth bump pad, which is spaced from the third bump pad with a second space, configured to, receive a complementary redundant signal having the same phase as the phase of the complementary main signal, wherein the first to fourth bump pads are positioned at the corners of a quadrangle with diagonals corresponding to the first and second spaces.

In accordance with still another embodiment of the present invention, an integrated circuit includes a first bump pad and a second bump pad that are spaced from each other with a first space configured to receive a first differential signal, and third bump pad and a fourth bump pad that are spaced from each other with a second space configured to receive a second differential signal having a frequency different from the frequency of the first differential signal. The first to fourth bump pads are positioned at the corners of a quadrangle with diagonals corresponding to the first and second spaces.

The integrated circuit may receive a desired signal, although the connection status of the bump pads is abnormal, so the operational stability may be improved.

### BRIEF DESCRIPTION OF THE DRAWINGS

FIG. 1 is a diagram illustrating an arrangement of bump pads in a conventional integrated circuit with a bump connection scheme.

FIG. 2 is a diagram illustrating an arrangement of bump pads in an integrated circuit in accordance with an embodiment of the present invention,

FIG. 3 is a circuit diagram illustrating a receiver circuit of the integrated circuit shown in FIG. 2.

FIG. 4 is a diagram illustrating an arrangement of bump pads in an integrated circuit in accordance with another embodiment of the present invention.

FIG. 5 is a block diagram illustrating a receiver circuit of the integrated circuit shown in FIG. 4.

FIG. 6 is a diagram illustrating an arrangement of bump pads in an integrated circuit in accordance with another embodiment of the present invention.

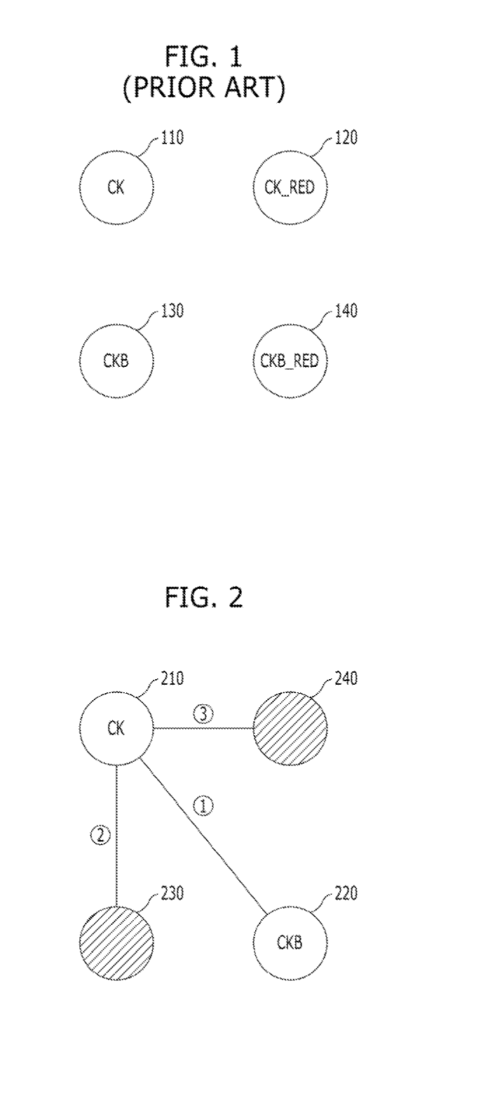

### DETAILED DESCRIPTION

Hereinafter, embodiments of the present invention will be described in detail with reference to the accompanying drawings.

However, the present invention is not limited to embodiments described below, but may be configured in various other forms. Therefore, the present embodiments are provided to complete the disclosure of the present invention and fully inform those skilled in the art of the scope of the present invention. Throughout the disclosure, reference numerals correspond directly to the like numbered parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence.

FIG. 2 is a diagram illustrating an arrangement of bump pads in an integrated circuit in accordance with an embodiment of the present invention.

Referring to FIG. 2, the integrated circuit includes first and second bump pads 210 and 220 receiving positive/negative main dock signals CK and CKB that are differential clock signals for a normal operation, and first and second random bump pads 230 and 240 receiving random signals for a repair operation on the differential clock signals. The first and second random bump pads 230 and 240 may comprise a redundant bump pads.

The first bump pad 210 receives the positive main clock signal CK, the second bump pad 220 receives the negative main clock signal CKB, and the first pump pad 210 and the second bump pad 220 are spaced with a first space \textcircled{1}. Further, the first and second random bump pads 230 and 240 receive random signals, the first random bump pad 230 is spaced with a second space \textcircled{2} from the first bump pad 210, and the second random bump pad 240 is spaced with a third space \textcircled{3} from the first bump pad 210. Here, the third space \textcircled{3} is smaller than the second space \textcircled{2} and the second space \textcircled{2} and the third space \textcircled{3} are smaller than the first space \textcircled{1}.

In the integrated circuit in accordance with the embodiment of the present invention, the first and second bump pads 210 and 220 receiving the positive main clock signal CK and the negative main clock signal CKB with the opposite phase to that of the positive main clock signal CK are spaced from each other with a the first space \textcircled{1}, and the first random bump pad 230 is spaced with the second space \textcircled{2} smaller than the first space \textcircled{1} or the second random bump pad 240 is spaced with the third space \textcircled{3} smaller than the first space \textcircled{1}. Therefore even if a short occurs between the first bump pad 210 and the first random bump pad 230 or between the first bump pad 210 and the second random bump pad 240 that are adjacent bump pads, respectively, the negative main clock signal CKB may be input to the integrated circuit through the second bump pad 220.

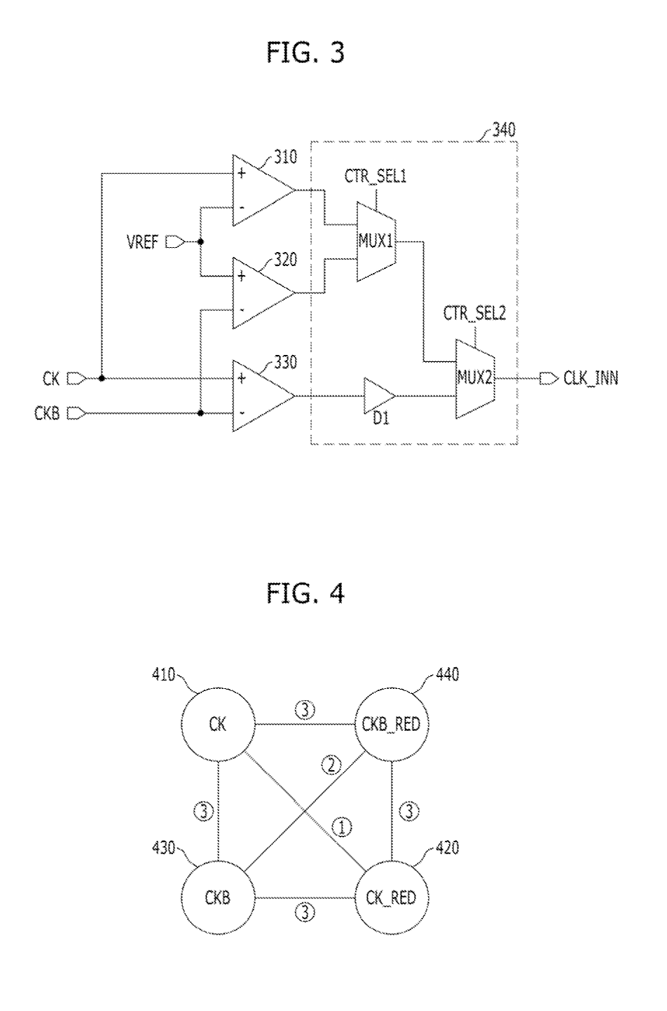

FIG. 3 is a circuit diagram illustrating a receiver circuit of the integrated circuit shown in FIG. 2, where the receiver circuit receives the positive main clock signal CK and the negative main clock signal CKB input through the first and second bump pads 210 and 220.

Referring to FIG. 3, the receiver circuit includes a first buffering unit 310 configured to buffer the positive main clock signal CK based on a given reference voltage VREF, a second buffering unit 320 configured to buffer the given reference voltage VREF based on the negative main clock signal CKB, a third buffering unit 330 configured to buffer the positive main clock signal CK based on negative main clock signal CKB, and an output control unit 340 configured to select and output one of output signals from the first to third buffering units 310, 320, and 330 as an internal clock signal CLK_INN.

The first and second buffering units 310 and 320 may be implemented by using a pseudo-differential type buffer. The third buffering unit 330 may be implemented by using a fully-differential type buffer. The output control unit 340 may include a first multiplexer MUX1 configured to select output signals of the first and second buffering units 310 and 320 in response to a first selection control signal CTR_SEL1, and a second multiplexer MUX2 configured to select output signals of the first multiplexer MUX1 and the third buffering unit 330 in response to a second selection control signal CTR_SEL2. Further, the output control unit 340 may include a delay buffer D1 for adjusting a delay of the output signal of the third buffering unit 330. The delay buffer D1 may delay the output signal of the third buffering unit 330 at a delay amount corresponding to that of the first multiplexer MUX1.

The output control unit 340 performs an operation for selectively outputting any one of the output signals from the first to third buffering units 310, 320, and 330 as the internal clock signal CLK_INN in response to the first and second selection control signals CTR_SEL1 and CTR_SEL2, where the values of the first and second selection control signals CTR_SEL1 and CTR_SEL2 are determined by a short status between the first and second bump pads 210 and 220 and the first and second random bump pads 230 and 240. There may be various methods of checking the short status, for example, boundary scan test or clock training.

A simple circuit operation is described hereafter with reference to FIGS. 2 and 3.

First, when a short occurs between the first bump pad 210 and any of the first and second random bump pads 230 and 240, the integrated circuit may stably receive the negative main clock signal CKB through the second bump pad 220. In this case, the second buffering unit 320 buffers the given reference voltage VREF based on the negative main clock signal CKB and the output control unit 340 selects and outputs the output signal from the second buffering unit 320 as the internal clock signal CLK_INN. For reference, the output signal from the second buffering unit 320 has the same phase as that of the positive main clock signal CK, and thus the internal clock signal CLK_INN also has the same phase as that of the positive main clock signal CK.

Next, when a short occurs between the second bump pad 220 and any of the first and second random bump pads 230 and 240, the integrated circuit may stably receive the positive main clock signal CK through the first bump pad 210. In this case, the first buffering unit 310 buffers the positive main clock signal CK based on the given reference voltage VREF and the output control unit 340 selects and outputs the output signal from the first buffering unit 310 as the internal clock signal CLK_INN.

Furthermore, when there is no short in both of the first and second bump pad 210 and 220, the integrated circuit may stably receive the positive main clock signal CK and the negative main clock signal CKB. In this case, the third buffering unit 330 buffers the positive main clock signal CK based on the negative main clock signal CKB, and the output control unit 340 selects and outputs the output signal from the third buffering unit 330 as the internal clock signal CLK_INN.

Even if a short occurs in any one of the first and second bump pads 210 and 220 receiving differential clock signals, the integrated circuit in accordance with the embodiment of the present invention may receive a clock signal through the other bump pad. Accordingly, the integrated circuit may stably generate the internal clock signal CLK_INN.

FIG. 4 is a diagram illustrating an arrangement of bump pads in an integrated circuit in accordance with another embodiment of the present invention.

Referring to FIG. 4, the integrated circuit includes a first bump pad 410 for receiving the positive main clock signal CK, a second bump pad 420 for receiving the positive redundant clock signal CK_RED a third bump pad 430 for receiving the negative main clock signal CKB, and a fourth bump pad 440 for receiving the negative redundant clock signal CKB_RED.

The positive/negative redundant clock signals CK_RED and CKB_RED are signals to substitute for the positive/negative main clock signals CK and CKB when there is a defect in the connection status of each of the first and third bump pads 410 and 430. The positive main clock signal CK and the positive redundant clock signal CK_RED have the same phase, and the negative main clock signal CKB and the negative redundant clock signal CKB_RED have the same phase. Further, the positive main clock signal CK and the negative main clock signal CKB are differential clock signals with opposite phases, and the positive redundant clock signal CK_RED and the negative redundant clock signal CKB_RED are also differential clock signals.

Meanwhile, the first bump pad 410 and the second bump pad 420 are spaced from each other with a first space \textcircled{1}, and the third bump pad 430 and the fourth bump pad 440 are spaced from each other with a second space \textcircled{2}. The first to fourth bump pads 410, 420, 430, and 440 are positioned at the corners of a quadrangle with diagonals corresponding to the first space \textcircled{1} and the second space \textcircled{2}. Although the sides of the quadrangle (hereinafter, referred to as a ‘third space’ and given reference number ‘\textcircled{3}’) may be different in length, they are smaller than the first space \textcircled{1} and the second space \textcircled{2}. In other words, the third space \textcircled{3} is smaller than the first space \textcircled{1} and also smaller than the second space \textcircled{2}. Therefore, if a short occurs between adjacent bump pads, the short may occur in the bump pad with the third space \textcircled{3} rather than the bump pads with the first space \textcircled{1} and the second space \textcircled{2}.

In the integrated circuit in accordance with the embodiment of the present invention, however, even if a short occurs between bump pads spaced with the third space \textcircled{3}, a clock signal having the same phase as the positive main clock signal CK and a clock signal having the same phase as the negative main clock signal CKB may be secured through the remaining bump pads of the integrated circuit.

In other words, for example, when a short occurs between the first bump pad 410 and the fourth bump pad 440 spaced with the third space \textcircled{3}, the integrated circuit may receive the positive redundant clock signal CK_RED having the same phase as that of the positive main clock signal CK through the second bump pad 420, and the negative main clock signal CKB through the third bump pad 430. That is, the integrated circuit may receive a clock signal having the same phase as the positive main clock signal CK and a clock signal having the same phase as the negative main clock signal CKB. Next, as another example, when a short occurs between the first bump pad 410 and the third bump pad 430 spaced with the third space \textcircled{3}, the integrated circuit may receive the positive redundant clock signal CK_RED through the second bump pad 420 and the negative redundant clock signal CKB_RED through the fourth bump pad 440. Therefore, similar to the above, the integrated circuit may receive a clock signal having the same phase as the positive main clock signal CK and a clock signal having the same phase as the negative main clock signal CKB.

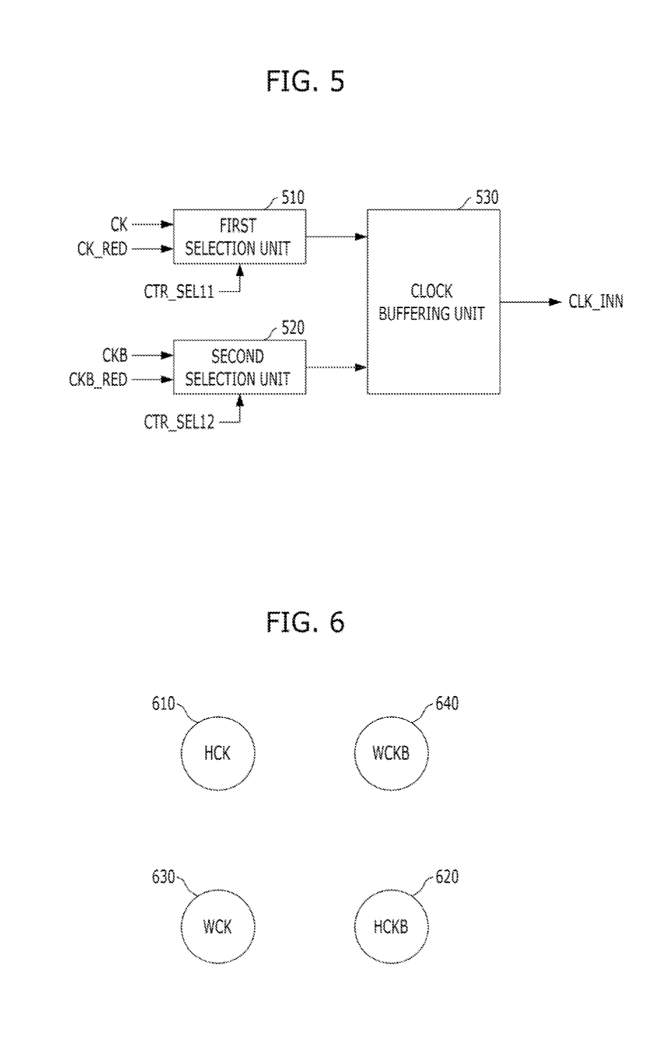

Meanwhile, it is exemplified that the receiver circuit shown in FIG. 3 receives the positive main clock signal CK and the negative main clock signal CKB. Therefore, two of the receiver circuit shown in FIG. 3 is needed, when the receiver circuit shown in FIG. 3 is applied to that of FIG. 4. The integrated circuit in accordance with the embodiment of the present invention, however, may be designed it the configuration of FIG. 5 to minimize the area of the receiver circuit,

FIG. 5 is a block diagram illustrating a receiver circuit of the integrated circuit shown in FIG. 4, where the receiver circuit generates an internal clock signal CLK_INN by receiving the positive/negative main clock signals CK and CKB and the positive/negative redundant clock signals CK_RED and CKB, RED that are input through the first to fourth bump pads 410, 420, 430, and 440.

Referring to FIG. 5, the receiver circuit includes first and second signal selection units 510 and 520 and a clock buffering unit 530.

The first signal selection unit 510 selectively outputs the positive main clock signal CK and the positive redundant clock signal CK_RED in response to a first selection control signal CTR_SEL11 and the second signal selection unit 520 selectively outputs the negative main clock signal CKB and the negative redundant dock signal CKB_RED in response to a second selection control signal CTR_SEL12. The first selection control signal CTR_SEL11 and the second selection control signal CTR_SEL12 have information for selecting clock signals to be used for generating the internal clock signal CLK_INN, depending on whether there is a short. Next, the clock buffering unit 530 generates the internal clock signal CLK_INN by buffering the output signal from the first signal selection unit 510 based on the output signal from the second signal selection unit 520. The clock buffering unit 530 may be implemented by using a fully-differential type buffer.

Detailed description is further provided hereafter with reference to FIGS. 4 and 5.

First, when a short occurs between the first and third bump pad 410 and 430, the first and second selection units 510 and 520 selectively output the positive/negative redundant clock signals CK_RED and CKB_RED input through the second and fourth bump pads 420 and 440 in response to the first and second selection control signals CTR_SEL11 and CTR_SEL12, respectively. Next, the clock buffering unit 530 generates the internal clock signal CLK_INN in response to the positive/negative redundant clock signals CK_RED and CKB_RED.

Next, when a short occurs between the second and fourth bump pad 420 and 440, the first and second selection units 510 and 520 selectively output the positive/negative main clock signals CK and CKB input through the first and third bump pads 410 and 430 in response to the first and second selection control signals CTR_SEL11 and CTR_SEL12, respectively. The clock buffering unit 530 generates the internal clock signal CLK_INN in response to the positive/negative main clock signals CK and CKB.

Furthermore, when a short occurs between the first and fourth bump pads 410 and 440 or between the second and third bump pads 420 and 430, similar to the above, the dock buffering unit 530 may receive differential dock signals, which means that the stable internal dock signal CLK_INN may be generated.

Meanwhile, the clock buffering unit 530 may receive stable differential clock signals in the cases described above. As described above, the clock buffering unit 530 may be implemented by using a fully-differential type buffer. However, to consider the case in which only one bump pad stably operates, the clock buffering unit 530 may be configured as in FIG. 3.

FIG. 6 is a diagram illustrating an arrangement of bump pads in an integrated circuit in accordance with another embodiment of the present invention. The arrangement of the bump pads shown in FIG. 6 is the same as that in FIG. 4, so detailed description is not provided and the configuration shown in FIG. 6 is different in the features of input clock signals in comparison to those shown in FIG. 4.

Referring to FIG. 6, the integrated circuit includes a first bump pad 610 for receiving a system clock signal HCK (hereinafter, referred to as a positive system clock signal), a second bump pad 620 for receiving a complementary system clock signal HCKB (hereinafter, referred to as a negative redundant clock signal), a third bump pad 630 for receiving a positive data clock signal WCK (hereinafter, referred to as a positive data clock signal), and a fourth bump pad 640 for receiving a complementary data clock signal WCKB (hereinafter, referred to as a negative data clock signal).

The positive system dock signal HCK and the negative system dock signal HCKB, which are signals with opposite phases, have frequencies that are used in control of a system. Further, The positive data dock signal WCK and the negative data dock signal WCKB, which are signals with opposite phases, have frequencies that are used in data processing. The frequencies of the positive/negative data clock signals WCK and WCKB may be higher (e.g., two times) than those of the positive/negative system clock signals HCK and HCKB.

Similar to the integrated circuit in accordance with the embodiment shown in FIG. 4, the integrated circuit in accordance with the embodiment of FIG. 6 may also receive a clock signal corresponding to a system clock signal HCK and a clock signal corresponding to a data clock signal WCK, even if a short occurs between adjacent bump pads.

Further, the integrated circuit in accordance with the embodiment of FIG. 6 may also include a receiver circuit such as that in FIG. 3. The integrated circuit may include a system clock receiver (not illustrated) that generates an internal system clock signal corresponding to the positive system clock signal HCK and a data clock receiver (not illustrated) that generates an internal data clock signal corresponding to the positive data clock signal WCK. Therefore, even if a short occurs in the first to fourth bump pads 610, 620, 630, and 640, the system clock receiver may generate the internal system dock signal by receiving at least one of the positive/negative system dock signals HCK and HCKB through the first and second bump pads 610 and 620 and may generate the internal data dock signal by receiving at least one of the positive/negative data dock signals WCK and WCKB through the third and fourth bump pads 630 and 640.

As set forth above, in accordance with the embodiments of the present invention, as first and second dock signals having the same characteristics are input through bump pads that are arranged diagonally to each other, at least one of the first and second clock signals may be secured, even if a short occurs between adjacent bump pads. Therefore, in accordance with the embodiments of the present invention, the stable internal clock signals may be generated, even if a short occurs between adjacent bump pads.

While the present invention has been described with respect to the specific embodiments, it should be noted that the embodiments is for describing, not limiting, the present invention. Further, it should be noted that the present invention may be achieved in various ways through substitution, change, and modification, by those skilled in the art without departing from the scope of the present invention.

Further, although it is exemplified in the embodiments that the signals input through the bump pads are clock signals, the present invention may be applied to other cases when different types of signals other than clock signals are input. Further, in other cases, similar to that the receiver circuit shown in FIGS. 3 and 5, which restore input dock signals into internal dock signals, the circuit corresponding to the receiver circuit has to restore signals corresponding to input signals.

1. An integrated circuit comprising:
first and second bump pads spaced from each other with a first gap, configured to receive differential signals; and
at least one redundant bump pad spaced from the first bump pad with a second gap smaller than the first gap, configured to receive a redundant signal,
wherein the differential signals are complementary signals, and the redundant signal is a substitute signal for the differential signals when there is a defect in a connection status of the first bump pad or the second bump pad.

2. The integrated circuit of claim 1, further comprising:
a signal generator configured to generate an internal signal corresponding to a signal input through any one of the first and second bump pads.

3. The integrated circuit of claim 2, wherein the signal generator comprises:
a first buffering unit configured to buffer a signal input through the first bump pad;
a second buffering unit configured to buffer a signal input through the second bump pad;
a third buffering unit configured to buffer signals input through the first and second bump pads; and
an output control unit outputting any one of output signals from the first to third buffering unit as the internal signal.

4. The integrated circuit of claim 3, wherein the first and second buffering units buffer the input signals based on a given reference voltage.

5. The integrated circuit of claim 3, wherein the output control unit controls the outputting of any one of the output signals from the first to third buffering unit, in response to whether there is a short between the first and second bump pads and the redundant bump pad.

6. The integrated circuit of claim 1, wherein the differential signals include a positive clock signal and a negative clock signal having a phase opposite to the phase of the positive clock signal.

7. An integrated circuit comprising:
a first bump pad configured to receive a main signal;
a second bump pad, which is spaced from the first bump pad with a first space, configured to receive a redundant signal having the same phase as the phase of the main signal;
a third bump pad configured to receive a complementary main signal having a phase opposite to the phase of the main signal; and
a fourth bump pad, which is spaced from the third bump pad with a second space, configured to receive a complementary redundant signal having the same phase as the phase of the complementary main signal,
wherein the first to fourth bump pads are positioned at the corners of a quadrangle with diagonals corresponding to the first and second spaces.

8. The integrated circuit of claim 7, further comprising a receiver circuit configured to generate an internal signal corresponding to the main signal.

9. The integrated circuit of claim 8, wherein the main signal and the complementary main signal are differential clock signals and the redundant signal and the complementary redundant signal are differential clock signals.

10. The integrated circuit of claim 8, wherein the receiver circuit comprises:
a first signal selection unit configured to selectively output the main signal and the redundant signal in response to a first selection control signal;
a second signal selection unit configured to selectively output the complementary main signal and the complementary redundant signal in response to a second selection control signal; and
a signal buffering unit configured to generate the internal signal by buffering an output signal from the first signal selection unit based on an output signal from the second signal selection unit.

11. The integrated circuit of claim 8, wherein the signal buffering unit comprises a fully-differential type buffer.

12. The integrated circuit of claim 10, wherein the first and second selection signals determined by a short status between the first to fourth bump pads

13. An integrated circuit comprising:
a first bump pad and a second bump pad that are spaced from each other with a first space configured to receive a first differential signals; and
a third bump pad and a fourth bump pad that are spaced from each other with a second space configured to receive a second differential signals having a frequency different from the frequency of the first differential signal,
wherein the first to fourth bump pads are positioned at the corners of a quadrangle with diagonals corresponding to the first and second spaces.

14. The integrated circuit of claim 13, further comprising:
a first receiver circuit configured to generate a first internal signal corresponding to a signal input through at least one of the first and second bump pads; and
a second receiver circuit configured to generate a second internal signal corresponding to a signal input through at least one of the third and fourth bump pads.

15. The integrated circuit of claim 14, wherein the first receiver circuit and the second receiver circuit each select corresponding bump pads from the first to fourth bump pads in response to selection control signals indicating whether there is a short in the first to fourth bump pads.

16. The integrated circuit of claim 13, wherein the first differential signals have a frequency for system controlling, and the second differential signals have a frequency for data processing.

17. An integrated circuit comprising:
a first bump pad suitable for receiving a positive main clock signal,
a second bump pad spaced from the first bump pad with a first gap, suitable for receiving a negative main clock signal, wherein the positive main clock signal and the negative main clock signal are complementary differential signals; and
at least one redundant bump pad spaced from the first bump pad with a second gap smaller than the first gap, suitable for receiving a positive redundant clock signal or a negative redundant clock signal,
wherein the positive redundant clock signal and the negative redundant clock signal are signals substitute for the positive main clock signal and the negative main clock signal when there is a defect in a connection status of the first bump pad or the second bump pad.
